(19) United States
(12) Patent Application Publication
(10) Pub. No.: US 2026/0105971 A1
(43) Pub. Date: Apr. 16, 2026

(54) INPUT BUFFER, MEMORY DEVICE AND MEMORY SYSTEM

(71) Applicant: YANGTZE MEMORY TECHNOLOGIES CO., LTD., Wuhan (CN)

(72) Inventors: Tao YANG, Wuhan (CN); Shuren LIU, Wuhan (CN); Shu XIE, Wuhan (CN); Jiawei CHEN, Wuhan (CN)

(21) Appl. No.: 19/055,390

(22) Filed: Feb. 17, 2025

(30) Foreign Application Priority Data
Oct. 15, 2024 (CN) 2024114440481

(51) Int. Cl. G11C 16/26; G11C 16/04; G11C 16/10

(52) U.S. Cl. CPC G11C 16/26; G11C 16/0483; G11C 16/10

(57) ABSTRACT

The present disclosure provides an input buffer, a memory device and a memory system, wherein the input buffer includes a first circuit and a second circuit coupled with the first circuit; wherein the first circuit comprises a first transistor pair including a first transistor and a second transistor, the first transistor and the second transistor each including two first electrodes and a second electrode located between the two first electrodes; and the second circuit comprises a second transistor pair including a third transistor and a fourth transistor, with a gate of the third transistor coupled to the two first electrodes of the first transistor, and a gate of the fourth transistor coupled to the two first electrodes of the second transistor.

### CROSS-REFERENCE TO RELATED APPLICATIONS

The present application claims priority to Chinese Patent Application No. 2024114440481, which was filed October 15, 2024, and is hereby incorporated herein by reference in its entirety.

### TECHNICAL FIELD

The present disclosure relates to the field of semiconductor technology, particularly to an input buffer, a memory device, and a memory system.

### BACKGROUND

The memory includes a volatile memory and a non-volatile memory. Volatile memory, such as dynamic random access memory (DRAM), has a faster read/write speed, but loses data stored therein after power is cut off. Non-volatile memory, such as NAND flash memory, retains data stored therein even when power is not supplied thereto.

### SUMMARY

Examples of the present disclosure provide an input buffer, a memory device and a memory system.

In order to achieve the above object, the technical solutions of the examples of the present disclosure are implemented as follows.

According to a first aspect, an example of the present disclosure provides an input buffer, including a first circuit and a second circuit coupled to the first circuit, wherein

the first circuit includes a first transistor pair including a first transistor and a second transistor, the first transistor and the second transistor each including two first electrodes and a second electrode located between the two first electrodes;

the second circuit includes a second transistor pair including a third transistor and a fourth transistor, with a gate of the third transistor coupled to the two first electrodes of the first transistor, and a gate of the fourth transistor coupled to the two first electrodes of the second transistor.

In an implementation, the first transistor is configured to receive an input voltage and output a first voltage, and the second transistor is configured to receive a reference voltage and output a second voltage;

the third transistor is configured to receive the first voltage and output a third voltage, and the fourth transistor is configured to receive the second voltage and output a fourth voltage.

In an implementation, the third transistor and the fourth transistor each include two first electrodes and a second electrode located between the two first electrodes, and the input buffer further includes:

a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

In an implementation, the first transistor pair and the second transistor pair are adjacent in a first direction, and the third transistor pair and the second transistor pair are adjacent in the first direction.

In an implementation, the first circuit further includes a first resistor and a second resistor, and the second circuit further includes a third resistor and a fourth resistor, wherein,

the first resistor and the second resistor are located on a side of the first transistor pair away from the second transistor pair in the first direction, wherein the first resistor is coupled to the two first electrodes of the first transistor, and the second resistor is coupled to the two first electrodes of the second transistor;

the third resistor and the fourth resistor are located on a side of the third transistor pair away from the second transistor pair in the first direction, wherein the third resistor is coupled to the two first electrodes of the third transistor, and the fourth resistor is coupled to the two first electrodes of the fourth transistor.

In an implementation, the input buffer further includes:

a fourth circuit coupled to the third circuit, wherein the fourth circuit includes a complementary metal-oxide-semiconductor (CMOS) pass gate and a first inverter connected in parallel, and the sixth transistor is coupled to the first inverter; and

a fifth circuit coupled to the fourth circuit, wherein the fifth circuit includes a plurality of second inverters connected in series, the fourth circuit is located between the third circuit and the fifth circuit in a second direction, and the second direction is perpendicular to the first direction.

In an implementation, the CMOS pass gate is located between the first inverter and the third circuit in the second direction, and the CMOS pass gate includes:

a seventh transistor and an eighth transistor arranged along the first direction, with a gate of the seventh transistor and a gate of the eighth transistor both extending along the first direction.

In a second aspect, an example of the present disclosure provides a memory device, including an input/output interface, wherein the input/output interface includes an input buffer including a first circuit and a second circuit coupled to the first circuit, wherein

the first circuit includes a first transistor pair including a first transistor and a second transistor, the first transistor and the second transistor each including two first electrodes and a second electrode located between the two first electrodes;

the second circuit includes a second transistor pair including a third transistor and a fourth transistor, with a gate of the third transistor coupled to the two first electrodes of the first transistor and a gate of the fourth transistor coupled to the two first electrodes of the second transistor.

In an implementation, the first transistor is configured to receive an input voltage and output a first voltage, and the second transistor is configured to receive a reference voltage and output a second voltage;

the third transistor is configured to receive the first voltage and output a third voltage, and the fourth transistor is configured to receive the second voltage and output a fourth voltage.

In an implementation, the third transistor and the fourth transistor each include two first electrodes and a second electrode located between the two first electrodes, and the input buffer further includes:

a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

In an implementation, the first transistor pair and the second transistor pair are adjacent in a first direction, and the third transistor pair and the second transistor pair are adjacent in the first direction.

In an implementation, the first circuit further includes a first resistor and a second resistor, and the second circuit further includes a third resistor and a fourth resistor, wherein

the first resistor and the second resistor are located on a side of the first transistor pair away from the second transistor pair in the first direction, wherein the first resistor is coupled to the two first electrodes of the first transistor, and the second resistor is coupled to the two first electrodes of the second transistor;

the third resistor and the fourth resistor are located on a side of the third transistor pair away from the second transistor pair in the first direction, wherein the third resistor is coupled to the two first electrodes of the third transistor, and the fourth resistor is coupled to the two first electrodes of the fourth transistor.

In an implementation, the input buffer further includes:

a fourth circuit coupled to the third circuit, wherein the fourth circuit includes a CMOS pass gate and a first inverter connected in parallel, and the sixth transistor is coupled to the first inverter; and

a fifth circuit coupled to the fourth circuit, wherein the fifth circuit includes a plurality of second inverters connected in series, wherein the fourth circuit is located between the third circuit and the fifth circuit in a second direction, and the second direction is perpendicular to the first direction.

In an implementation, the CMOS pass gate is located between the first inverter and the third circuit in the second direction, and the CMOS pass gate includes:

a seventh transistor and an eighth transistor arranged along the first direction, with a gate of the seventh transistor and a gate of the eighth transistor both extend along the first direction.

According to a third aspect, an example of the present disclosure provides a memory system, including:

at least one memory device according to any one of the above examples; and

a memory controller coupled with the at least one memory device and configured to control the memory device.

In the technical solution provided by the present disclosure, the input buffer includes a first circuit, a second circuit coupled to the first circuit, and a third circuit coupled to the second circuit. A first transistor pair in the first circuit, a second transistor pair in the second circuit and a third transistor pair in the third circuit can be placed in a concentrated manner, so that the length of the signal line between the transistor pair can be reduced, the parasitic capacitance is reduced, and the transmission speed of the voltage signal is improved. In addition, the transistors in the first transistor pair, the second transistor pair and the third transistor pair each include two first electrodes and a second electrode located between the two first electrodes, with a gate of one transistor in the next transistor pair coupled to the two first electrodes of one transistor in the previous transistor pair, so that current distribution is more uniform, thereby reliability of voltage signal transmission can be improved.

### BRIEF DESCRIPTION OF THE DRAWINGS

FIG. 1 is a schematic diagram of a memory system provided in an example of the present disclosure.

FIG. 2 is a schematic diagram of a memory card provided in an example of the present disclosure.

FIG. 3 is a schematic diagram of a solid state disk provided in an example of the present disclosure.

FIG. 4 is a first schematic diagram of a memory device provided in an example of the present disclosure.

FIG. 5 is a second schematic diagram of a memory device provided in an example of the present disclosure.

FIG. 6 is a third schematic diagram of a memory device provided in an example of the present disclosure.

FIG. 7 is a schematic diagram of a partial structure in an input/output interface provided in an example of the present disclosure.

FIG. 8 is a schematic diagram of the composition of an input buffer provided in an example of the present disclosure.

FIG. 9 is a schematic circuit diagram of a first circuit provided in an example of the present disclosure.

FIG. 10 is a schematic circuit diagram of a second circuit provided in an example of the present disclosure.

FIG. 11 is a schematic circuit diagram of a third circuit, a fourth circuit and a fifth circuit provided in an example of the present disclosure.

FIG. 12 is a schematic diagram of a layout structure of an input buffer provided in an example of the present disclosure.

FIG. 13 is a schematic diagram of a layout structure of a transistor provided in an example of the present disclosure.

FIG. 14 is a schematic diagram of a layout structure of a partial structure in an input buffer provided in an example of the present disclosure.

### DETAILED DESCRIPTION

Exemplary implementations of the present disclosure will be described in more detail below with reference to the accompanying drawings. While exemplary implementations of the present disclosure are shown in the drawings, the present disclosure may be implemented in various forms and should not be limited by the specific implementations set forth herein. Rather, these implementations are provided to enable a more thorough understanding of the present disclosure and to fully convey the scope of the present disclosure to those skilled in the art.

In the following description, numerous specific details are given in order to provide a more thorough understanding of the present disclosure. It will be apparent to those skilled in the art, however, that the present disclosure may be practiced without one or more of these details. In other examples, to avoid confusion with the present disclosure, some technical features known in the art are not described; for example, not all features of the actual examples are described herein, and well-known functions and structures are not described in detail.

In the drawings, like reference numerals refer to like elements throughout.

Spatially relative terms such as “under”, “below”, “beneath”, “lower”, “over”, “above”, etc., may be used herein for ease of description to describe one element or feature and other elements or features as shown in the figures. It should be appreciated that the spatially relative terms are intended to encompass different orientations of the device in use or operation in addition to the orientation depicted in the figures. For example, if the devices in the figures are flipped, then the element or features described as “below” or “under” or “beneath” other elements will be oriented “on” other elements or features. Thus, the exemplary terms “below” and “under” may include both upper and lower orientations. The devices may be otherwise oriented (rotated 90 degrees or other orientations) and the spatially relative descriptors used herein is interpreted accordingly.

The terminology used herein is for the purpose of describing particular examples only and is not intended as a limitation to the present disclosure. As used herein, the singular forms “a,” “an,” and “the” are intended to include plural forms as well, unless the context clearly indicates otherwise. The terms “comprise” and/or “include”, when used in this specification, determine the presence of stated features, integers, steps, operations, elements, and/or components, but do not preclude the presence or addition of one or more other features, integers, steps, operations, elements, components, and/or groups. As used herein, the term “and/or” includes any and all combinations of related listed items.

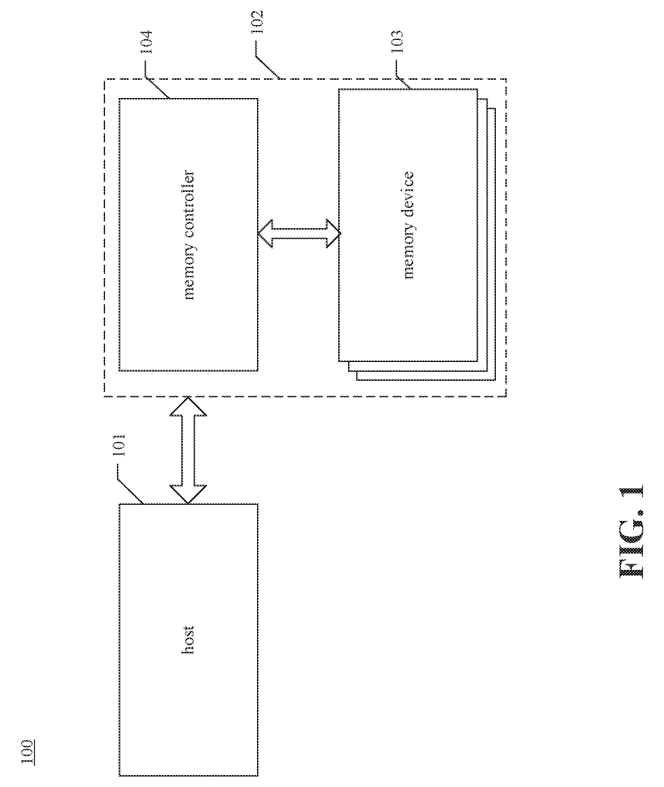

FIG. 1 is a schematic diagram of a memory system provided in an example of the present disclosure. In an example of the present disclosure, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a storage therein. As shown in FIG. 1, the system 100 may include a host 101 and a memory system 102, which may include one or more memory devices 103 and a memory controller 104. The host 101 may include a processor of an electronic device, for example, a central processing unit (CPU), or a system on a chip (SoC), for example, an application processor (Application Processor, AP). The host 101 may be configured to send or receive data to or from the memory system 102.

In some implementations, the memory controller 104 is coupled to the memory device 103 and the host 101 and is configured to control the memory device 103. The memory controller 104 may manage data stored in the memory device 103 and communicate with the host 101. In some examples, the memory controller 104 is designed to operate in a low duty cycle environment, such as in a secure digital card, compact flash card (CFC), universal serial bus (USB) flash drive, or other medium for use in electronic devices such as personal computers, digital cameras, mobile phones, and the like. In other examples, the memory controller 104 is designed to operate in a high duty cycle environment, such as a solid state disk or embedded Multi-Media Card (eMMC).

In some examples, the memory controller 104 and the one or more memory devices 103 may be integrated into various types of storage devices, for example, the memory system 102 may be implemented and packaged into different types of terminal electronics.

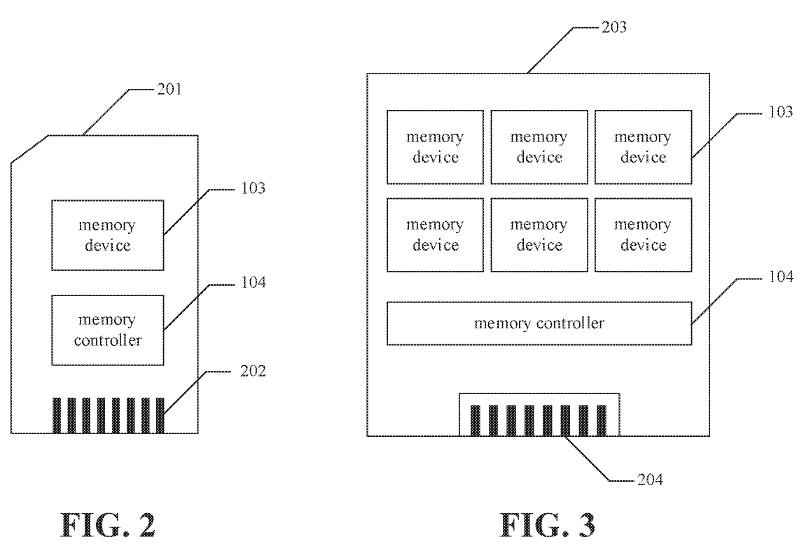

In one example as shown in FIG. 2, the memory controller 104 and the single memory device 103 may be integrated into the memory card 201. The memory card 201 may be one of a compact flash memory card, a smart media card (SMC), a memory stick (MS), a multimedia card (MMC), for example, an RS-MMC, an MMCmicro, an eMMC, or the like, a secure digital card, for example, a Mini SD card, a Micro SD card, an SDHC card, or the like, and a universal flash memory card. The memory card 201 may also include a memory card connector 202 that couples the memory card 201 with a host (e.g., host 101 in FIG. 1). In another example as shown in FIG. 3, the memory controller 104 and the plurality of memory devices 103 may be integrated into SSD 203. SSD 203 may also include an SSD connector 204 that couples SSD 203 with a host (e.g., host 101 in FIG. 1). In some implementations, the storage capacity and/or operating speed of SSD 203 is greater than the storage capacity and/or operating speed of memory card 201.

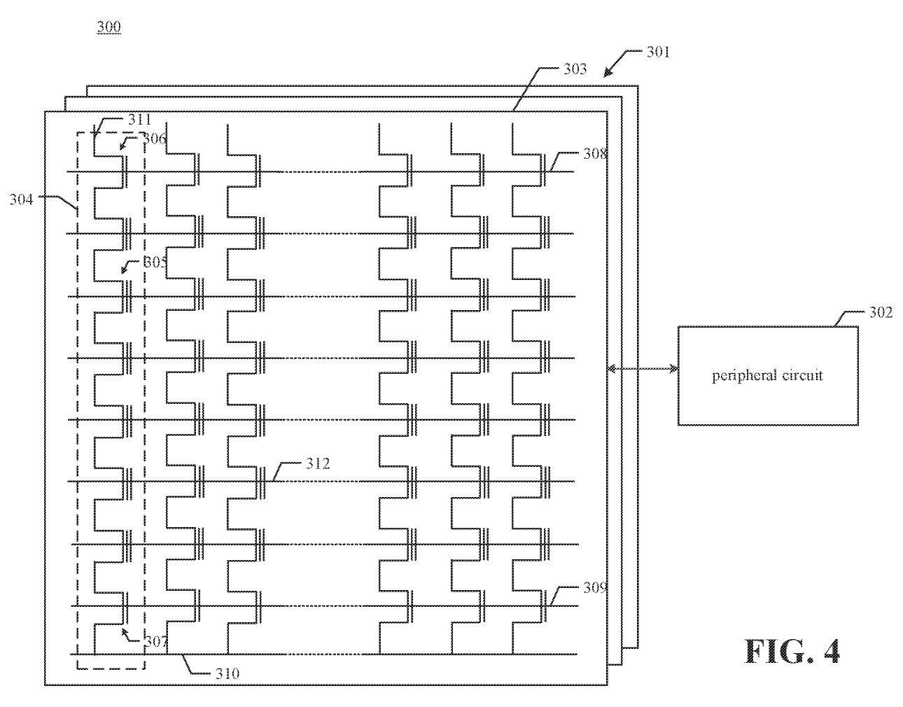

FIG. 4 is a schematic diagram of a memory device provided in an example of the present disclosure. Memory device 300 may be an example of memory device 103 in FIG. 1. The memory device 300 may include a memory array 301 and a peripheral circuit 302 coupled to the memory array 301. Taking a case in which the memory array 301 is a three-dimensional NAND type memory array as an example for description, the memory cell 305 is a NAND memory cell, the memory cell 305 is provided in the form of an array of memory strings 304, and each memory string 304 extends vertically above a substrate (not shown). In some implementations, each memory string 304 includes a plurality of memory cells 305 coupled in series and stacked vertically. Each memory cell 305 may retain a continuous analog value, e.g., voltage or charge, depending on the number of electrons trapped within the area of the memory cell 305. Each memory cell 305 may be a floating gate type memory cell including a floating gate transistor, or a charge trapping type memory cell including a charge trapping transistor.

In some examples, each memory cell 305 is a Single Level Cell (SLC) having two possible memory states and thus may store one bit of data. For example, the first memory state “0” may correspond to a first voltage range and the second memory state “1” may correspond to a second voltage range. In some examples, each memory cell 305 is a multi-level cell capable of storing more than a single bit of data in four or more memory states, e.g., a multi-level cell (MLC) storing two bits per cell, a triple level cell (TLC) per cell storing three bits, or a Quad-Level Cell (QLC) storing four bits per cell.

As shown in FIG. 4, each memory string 304 may include a bottom select transistor (BST) 307 at its source terminal and a top select transistor (TST) 306 at its drain terminal. The bottom select transistor 307 and the top select transistor 306 may be configured to activate the selected memory string 304 during read and program operations. In some examples, the sources of the memory strings 304 in the same memory block 303 may be coupled through a common source line (CSL) 310. For example, all memory strings 304 in the same memory block 303 have a array common source (“ACS”). According to some examples, the top select transistor 306 of each memory string 304 is coupled to a respective bit line (BL) 311, such that data may be read from the bit line 311 or written via an output bus (not shown). In some examples, each memory string 304 is configured to be selected or deselected by applying a select voltage (e.g., a voltage higher than a threshold voltage of the top select transistor 306) or a deselect voltage (e.g., 0V) to a top select gate (TSG) of the respective top select transistor 306 though one or more top select lines (TSL) 308 and/or by applying a select voltage (e.g., a voltage higher than a threshold voltage of the bottom select transistor 307) or a deselect voltage (e.g., 0V) to a bottom select gate (BSG) of the respective bottom select transistor 307 through one or more bottom select lines (BSL) 309.

As shown in FIG. 4, the memory string 304 may be organized into a plurality of memory blocks 303, each of which may have a common source line 310. In some implementations, each memory block 303 is a basic data unit for an erase operation, e.g., all memory cells 305 on the same memory block 303 are erased simultaneously. To erase the memory cells 305 in the selected memory block, the common source line 310 coupled to the selected memory block and an unselected memory block in the same plane as the selected memory block may be biased with an erase voltage. In some examples, the erase operation may be performed at a half memory block level, at a quarter memory block level, or at a level having any suitable number of memory blocks or any suitable fraction of the memory block. The memory cells 305 of adjacent memory strings 304 may be coupled by the word lines 312 that select which row of the memory cells 305 is affected by the read or program operations.

In some examples, the peripheral circuit 302 may include any suitable analog, digital, and mixed-signal circuit to enable operation of the memory array 301 by applying voltage signals and/or current signals to and sensing voltage signals and/or current signals from each target memory cell 305 through the bit lines 311, the word lines 312, the common source lines 310, the bottom select lines 309, and the top select lines 308. The peripheral circuit 302 may include various types of peripheral circuit formed using metal-oxide-semiconductor technology.

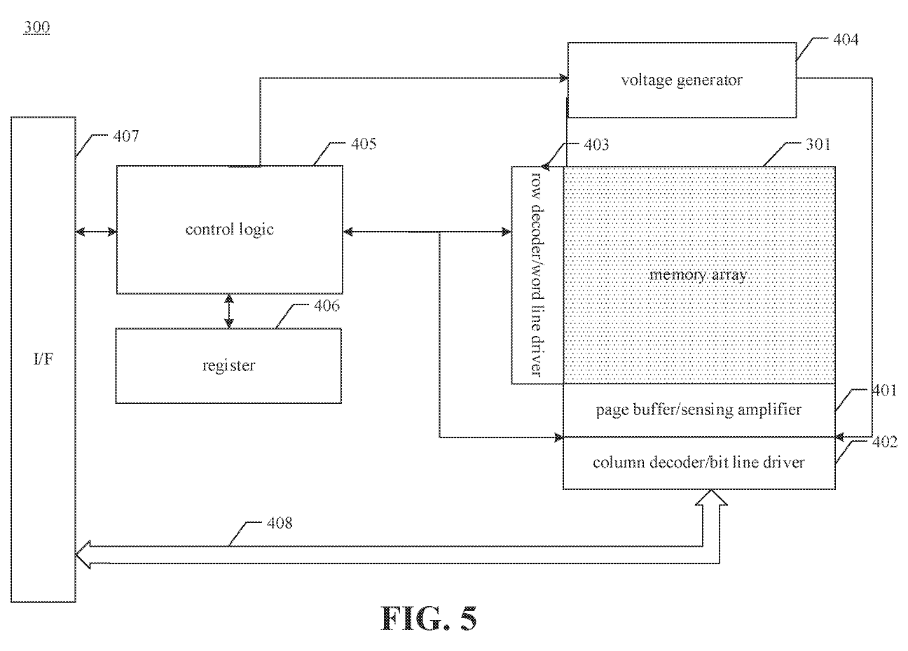

FIG. 5 shows some exemplary peripheral circuits including a page buffer/sense amplifier 401, a column decoder/bit line driver 402, a row decoder/word line driver 403, a voltage generator 404, a control logic 405, a register 406, an input/output interface 407, and a data bus 408. In some examples, additional peripheral circuits not shown in FIG. 5 may also be included.

The page buffer/sense amplifier 401 may be configured to read data from and program (write) data to the memory array 301 according to control signals from the control logic 405. In one example, the page buffer/sense amplifier 401 may store a page of programming data (write data) to be programmed to the memory array 301. In another example, the page buffer/sense amplifier 401 may perform a program verify operation to ensure that data has been properly programmed into memory cells coupled to the selected word line. In yet another example, the page buffer/sense amplifier 401 may also sense a low power signal from the bit line representing a data bit stored in the memory cell, and amplify the small voltage swing to an identifiable logic level in a read operation. Column decoder/bit line driver 402 may be configured to be controlled by the control logic 405 and select one or more memory strings by applying a bit line voltage generated from voltage generator 404.

The row decoder/word line driver 403 may be configured to be controlled by the control logic 405 and select/deselect a memory block of the memory array 301 and select/deselect a word line of the memory block. The row decoder/word line driver 403 may also be configured to drive the word line using a word line voltage generated from the voltage generator 404. In some implementations, the row decoder/word line driver 403 may also select/deselect and drive the bottom select line and the top select line. As described in detail below, the row decoder/word line driver 403 is configured to perform a program operation on the memory cells coupled to the selected word line(s). The voltage generator 404 may be configured to be controlled by the control logic 405 and generate the word line voltages (e.g., read voltages, program voltages, pass voltages, local voltages, verify voltages, etc.), bit line voltages, and source line voltages to be supplied to the memory array 301.

The control logic 405 may be coupled to each peripheral circuit described above and configured to control operation of each peripheral circuit. The register 406 may be coupled to the control logic 405 and include status registers, command registers, and address registers for storing status information, command operation codes (OP codes), and command addresses for controlling operation of each peripheral circuit. The input/output interface 407 may be coupled to the control logic 405 and may be coupled to the column decoder/bit line driver 402 via the data bus 408. The input/output interface 407 may include an input buffer and an output buffer, wherein the input buffer may buffer commands or data received from the memory controller, and the output buffer may buffer status information or data that needs to be sent to the memory controller.

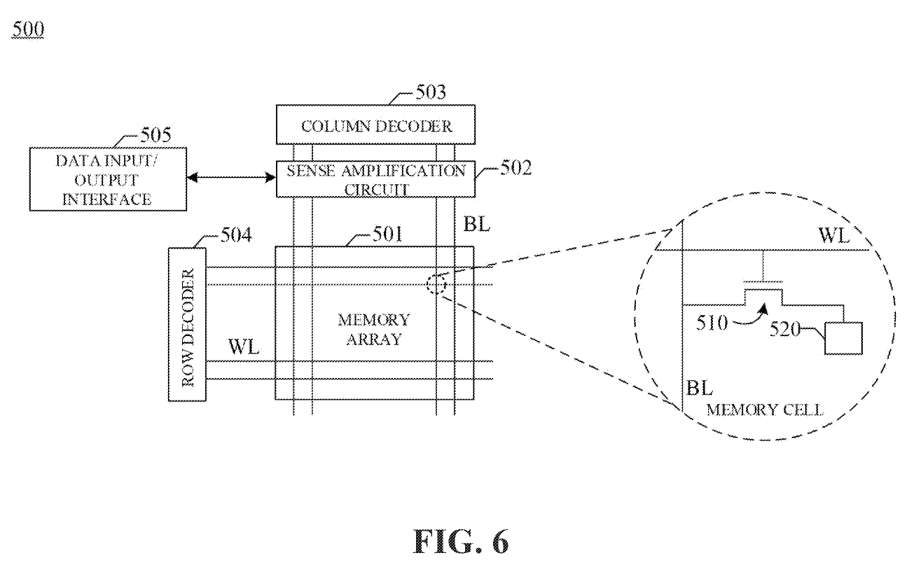

The above example takes the case in which the memory system includes a three-dimensional NAND type memory as an example, however, in some other examples, the memory system may further include other types of memory devices, and FIG. 6 is a schematic diagram of a memory device provided in an example of the present disclosure. Referring to FIG. 6, a peripheral circuit in the memory device 500 may include a sense amplification circuit 502, a column decoder 503, a row decoder 504, a data input/output interface 505, and the like. The data input/output interface 505 may include an input buffer and an output buffer, wherein the input buffer may temporarily store the data that needs to be written to the memory array 501, and the output buffer may temporarily store the data read from the memory array 501. The peripheral circuit is coupled to the memory array 501 through the bit lines BL and the word lines WL. The memory array 501 includes a plurality of memory cells arranged in an array, the memory cells in the same row are coupled to the word line WL, and the memory cells in the same column are coupled to the bit line BL. Each memory cell includes a gating element 510 and a storage unit 520, with the word line WL connected to the gate of the gating element 510, the bit line BL connected to one of the source and the drain of the gating element 510, and the other of the source and the drain of the gating element 510 connected to the storage unit 520. The respective memory cell in the memory array 501 may be independently accessed by specifying the row address and the column address, and the read operation, write operation or refresh operation can be performed to the data stored therein.

In some examples, if the memory device 500 is a dynamic random access memory (DRAM), the storage unit 520 is a capacitor, and the capacitor can achieve data storage based on the amount of charge on its electrode plate. If the memory device 500 is a phase change memory (PCM), the storage unit 520 is a phase change element including a chalcogenide, and the phase change element can achieve data storage based on a difference in electrical resistivity between its crystalline state and amorphous state. If the memory device 500 is a ferroelectric memory, the storage unit 520 is a ferroelectric capacitor, and the ferroelectric capacitor may achieve data storage based on a difference between different polarization states generated by the ferroelectric crystal under an external electric field.

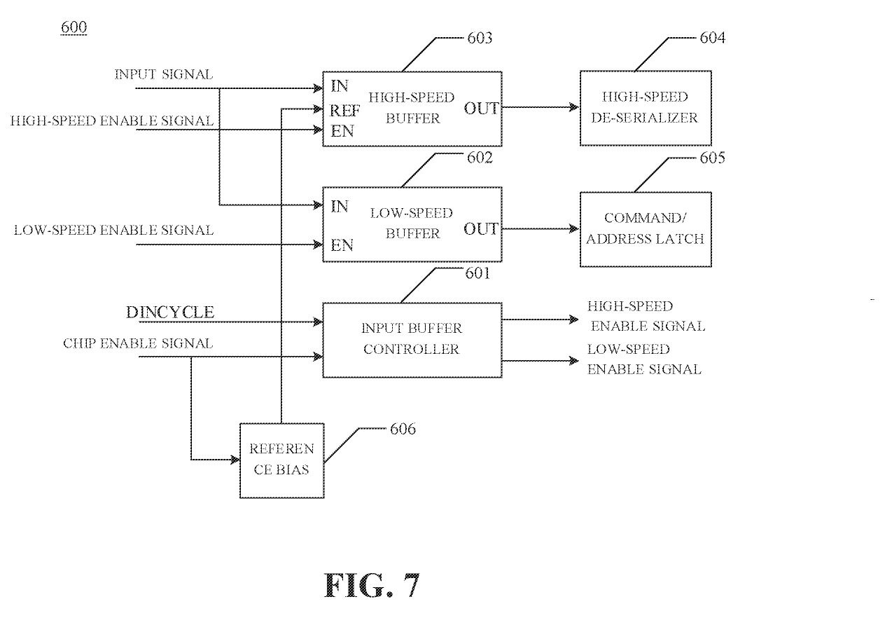

FIG. 7 is a schematic diagram of a partial structure in an input/output interface 600 provided in an example of the present disclosure. Here the input/output interface 600 may be an input/output interface 407 in the memory device 300 shown in FIG. 5 or a data input/output interface 505 in the memory device 500 shown in FIG. 6. The input/output interface 600 may include a high-speed buffer 603, a low-speed buffer 602, an input buffer controller 601, a reference bias 606, a high-speed de-serializer 604, and a command/address latch 605. The input buffer controller 601 is configured to receive a chip enable signal and a DINCYCLE signal, and an input signal may include a command signal, an address signal, and/or a data signal. The DINCYCLE signal is configured to indicate whether the input signal is a data signal. When the input signal is a data signal, the input buffer controller 601 may generate a high-speed enable signal and transfer the high-speed enable signal to the high-speed buffer 603 to enable the high-speed buffer 603. When the input signal is a command signal or an address signal, the input buffer controller 601 may generate a low-speed enable signal and transmit the low-speed enable signal to the low-speed buffer 602 to enable the low-speed buffer 602. The chip enable signal may also enable the reference bias 606 that provides a reference voltage to the high-speed buffer 603 when the high-speed buffer 603 is enabled. Furthermore, the high-speed buffer 603 may further transmit the data signal to the high-speed de-serializer 604, and the low-speed buffer 602 may further transmit the command/address signal to the command/address latch 605.

In the above input/output interface, the performance of the high-speed buffer limits the reliability of data transmission between the memory controller and the memory device to a certain extent, therefore, in order to further improve the performance of the memory system, the performance of the high-speed buffer needs to be further improved. In this regard, the present disclosure provides the following implementations.

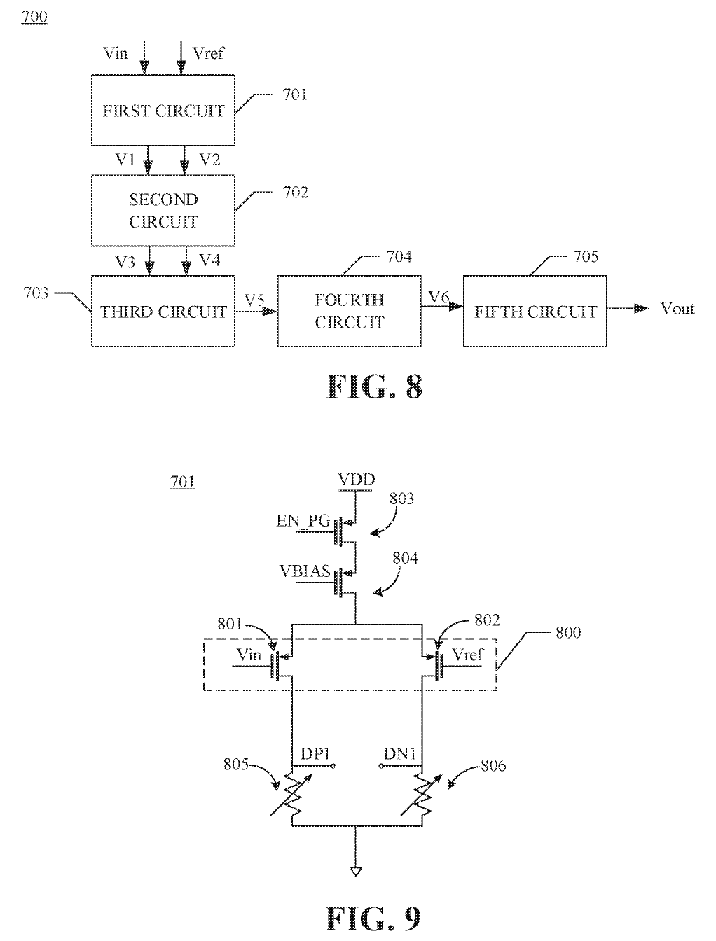

The present disclosure provides an input buffer, as shown in FIG. 8, the input buffer 700 includes a first circuit 701, a second circuit 702, a third circuit 703, a fourth circuit 704, and a fifth circuit 705.

In some examples, the first circuit 701 and the second circuit 702 are both Current Mode Logic (CML) circuits. The first circuit 701 may be configured to receive the input voltage Vin and the reference voltage Vref, and output the first voltage V19/055,390 and the second voltage V2, and the second circuit 702 may be configured to receive the first voltage V1 and the second voltage V2, and output the third voltage V3 and the fourth voltage V4. Here, the first voltage V1 and the second voltage V2 are differential voltages, and the third voltage V3 and the fourth voltage V4 are differential voltages obtained after amplifying the first voltage V1 and the second voltage V2, for example, the first circuit 701 may convert the single-ended input voltage Vin into a differential voltage with a stronger anti-interference capability, and the second circuit 702 may further amplify the differential voltage to improve reliability of the transmission of the voltage signal in the input buffer.

In a specific example, FIG. 9 is a schematic circuit diagram of a first circuit 701, and referring to FIG. 8 and FIG. 9, the first circuit 701 includes a first transistor pair 800 including a first transistor 801 and a second transistor 802, in which a gate of the first transistor 801 receives the input voltage Vin, and outputs the first voltage V1, and a gate of the second transistor 802 receives the reference voltage Vref, and outputs the second voltage V2. In addition, the first circuit 701 further includes a transistor 803 and a transistor 804 coupled between the power supply voltage VDD and the first transistor pair 800, and a first resistor 805 and a second resistor 806 coupled between the first transistor pair 800 and a ground terminal. A gate of the transistor 803 receives a enable signal EN_PG, a gate of the transistor 804 receives a bias voltage VBIAS, both ends of the first resistor 805 are respectively coupled to the first transistor 801 and the ground terminal, and both ends of the second resistor 806 are respectively coupled to the second transistor 802 and the ground terminal. Here, the first transistor 801, the second transistor 802, the transistor 803 and the transistor 804 are all PMOS, the enable signal EN_PG may turn on the transistor 803, the transistor 804 receiving the bias voltage VBIAS may provide a current source for the circuit, and the first resistor 805 and the second resistor 806 may be variable resistors for adjusting the relative magnitude of the first voltage V1 and the second voltage V2 output by the first circuit 701.

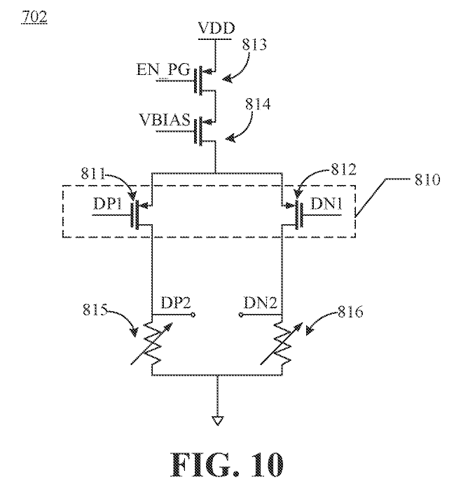

In an example, FIG. 10 is a schematic circuit diagram of the second circuit 702, and with reference to FIG. 8, FIG. 9 and FIG. 10, the second circuit 702 includes a second transistor pair 810 including a third transistor 811 and a fourth transistor 812, in which a gate of the third transistor 811 is coupled to a drain of the first transistor 801 through a signal line DP1, and receives the first voltage V1 and outputs the third voltage V3, a gate of the fourth transistor 812 is coupled to a drain of the second transistor 802 through a signal line DN1, and receives the second voltage V2 and outputs the fourth voltage V4. In addition, the second circuit 702 further includes a transistor 813 and a transistor 814 coupled between the supply voltage VDD and the second transistor pair 810, and a third resistor 815 and a fourth resistor 816 coupled between the second transistor pair 810 and the ground terminal. A gate of the transistor 813 receives the enable signal EN_PG, a gate of the transistor 814 receives the bias voltage VBIAS, both ends of the third resistor 815 are respectively coupled to the third transistor 811 and the ground terminal, and both ends of the fourth resistor 816 are respectively coupled to the fourth transistor 812 and the ground terminal. Here, the third transistor 811, the fourth transistor 812, the transistor 813 and the transistor 814 are all PMOS, the enable signal EN_PG may turn on the transistor 813, the transistor 814 receiving the bias voltage VBIAS may provide a current source for the circuit, and the third resistor 815 and the fourth resistor 816 may be variable resistors for adjusting the relative magnitude of the third voltage V3 and the fourth voltage V4 output by the second circuit 702.

In some examples, the third circuit 703 is an operational transconductance-amplifier (OTA) circuit, the fourth circuit 704 is an active inductance circuit, and the fifth circuit 705 is an inverter series circuit. Referring back to FIG. 8, the third circuit 703 may be configured to receive the third voltage V3 and the fourth voltage V4, and output a fifth voltage V5, the fourth circuit 704 may be configured to receive the fifth voltage V5 and output a sixth voltage V6, and the fifth circuit 705 is configured to receive the sixth voltage V6 and output the output voltage Vout. Here, the output voltage Vout is a voltage obtained after amplifying the input voltage Vin.

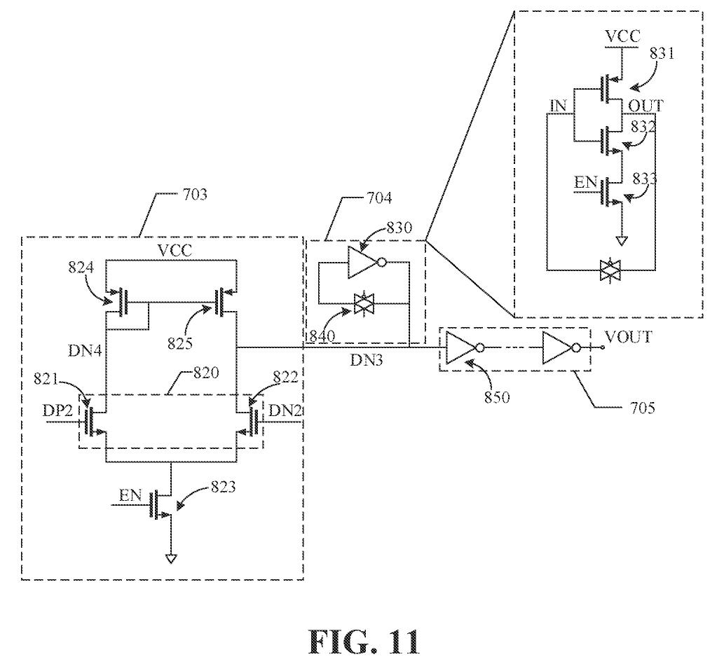

In an example, FIG. 11 is a schematic circuit diagram of a third circuit 703, a fourth circuit 704 and a fifth circuit 705. Referring to FIG. 8, FIG. 10 and FIG. 11, the third circuit 703 includes a third transistor pair 820 including a fifth transistor 821 and a sixth transistor 822, in which a gate of the fifth transistor 821 is coupled to a drain of the third transistor 811 through a signal line DP2, and receives the third voltage V3, and a gate of the sixth transistor 822 is coupled to a drain of the fourth transistor 812 through a signal line DN2, and receives the fourth voltage V4. In addition, the third circuit 703 further includes a transistor 824 and a transistor 825 whose gate is coupled to each other, wherein a source of the transistor 824 and a source of the transistor 825 are both coupled to the power supply voltage VCC, a drain and a gate of the transistor 824 are both coupled to the fifth transistor 821, and a drain of the transistor 825 is coupled to the sixth transistor 822, and is coupled to the fourth circuit 704 through a signal line DN3. The third circuit 703 may convert the differential voltage (the third voltage V3 and the fourth voltage V4) into the amplified single-ended voltage (the fifth voltage V5).

In an example, with reference to FIG. 8 and FIG. 11, the fourth circuit 704 includes a CMOS pass gate 840 and a first inverter 830 connected in parallel, in which the first inverter 830 further includes a transistor 831 and a transistor 832, the fourth circuit 704 further includes a transistor 833 coupled between the transistor 832 and the ground terminal, and a gate of the transistor 833 receives the enable signal EN. An input terminal IN of the first inverter 830 may receive the fifth voltage V5 and output the sixth voltage V6 through an output terminal OUT, and the CMOS pass gate 840 is coupled between the input terminal IN and the output terminal OUT of the first inverter 830, so that the bandwidth of the voltage signal output by the third circuit 703 may be expanded while maintaining the amplification gain of the third circuit 703.

In an example, with reference to FIG. 8 and FIG. 11, the fifth circuit 705 includes a plurality of second inverters 850 connected in series, in which the fifth circuit 705 may receive the sixth voltage V6 and output the waveform modulated output voltage Vout.

In the above example, the input buffer is composed of a plurality of circuits having different functions, wherein the first circuit 701 may convert the input voltage Vin into a differential voltage (the first voltage V1 and the second voltage V2) having higher anti-interference capability, the second circuit 702 may further amplify the first voltage V1 and the second voltage V2 to obtain the third voltage V3 and the fourth voltage V4, the third circuit 703 may convert the third voltage V3 and the fourth voltage V4 to a single-ended voltage (the fifth voltage V5, which is the amplified input voltage Vin), the fourth circuit 704 may extend the bandwidth of the fifth voltage V5 to obtain the sixth voltage V6 with a stronger anti-interference capability, and the fifth circuit 705 may perform waveform modulation on the sixth voltage V6 to obtain the output voltage Vout. Thus, the input buffer has higher reliability.

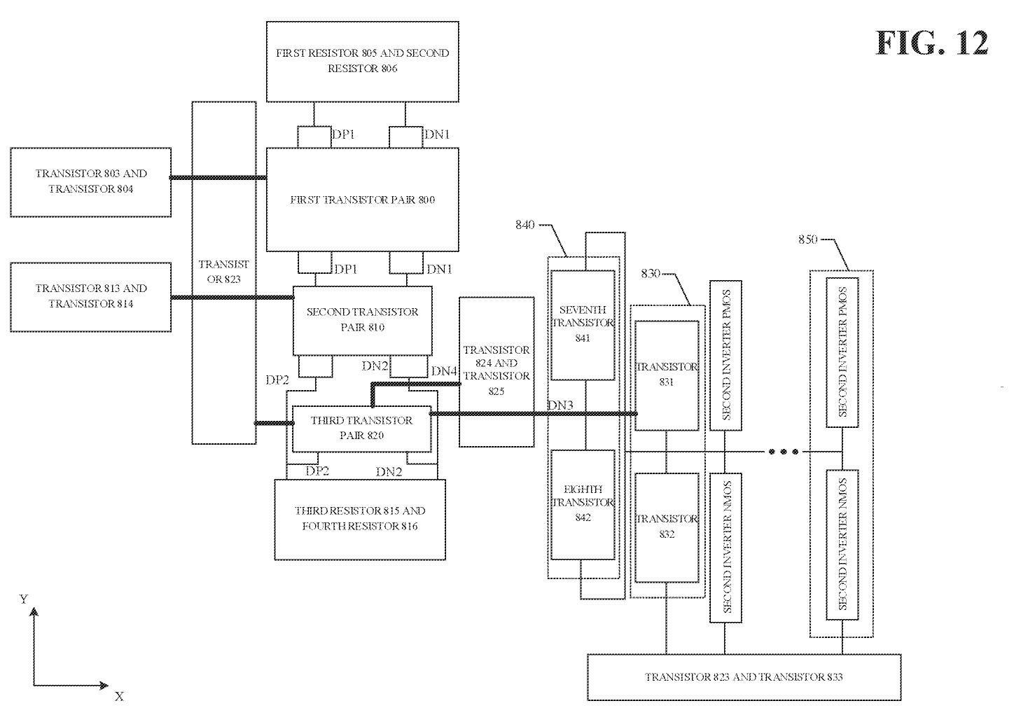

In some examples, FIG. 12 is a schematic diagram of a layout structure of an input buffer provided by an example of the present disclosure. With reference to FIG. 8 to FIG. 12, the input buffer includes a first circuit 701, a second circuit 702 coupled to the first circuit 701, and a third circuit 703 coupled to the second circuit 702, wherein the first circuit 701 includes a first transistor pair 800 including a first transistor 801 and a second transistor 802, the second circuit 702 includes a second transistor pair 810 including a third transistor 811 and a fourth transistor 812, and the third circuit 703 includes a third transistor pair 820 including a fifth transistor 821 and a sixth transistor 822. The first transistor 801 in the first transistor pair 800 is coupled to the third transistor 811 in the second transistor pair 810 through a signal line DP1, the second transistor 802 in the first transistor pair 800 is coupled to the fourth transistor 812 in the second transistor pair 810 through a signal line DN1, the third transistor 811 in the second transistor pair 810 is coupled to the fifth transistor 821 in the third transistor pair 820 through a signal line DP2, and the fourth transistor 812 in the second transistor pair 810 is coupled to the sixth transistor 822 in the third transistor pair 820 through a signal line DN2.

In the example of the present disclosure, as shown in FIG. 12, the first transistor pair 800 and the second transistor pair 810 are adjacent in the first direction, and the second transistor pair 810 and the third transistor pair 820 are adjacent in the first direction, here the first direction is the Y direction. Therefore, by placing the first transistor pair 800, the second transistor pair 810 and the third transistor pair 820 in a concentrated manner, length of the signal line can be shortened, and the parasitic capacitance of the signal line can be reduced, thereby improving the transmission speed of the voltage signal in the input buffer.

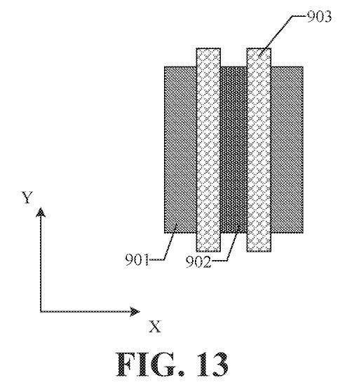

In some examples, FIG. 13 is a schematic diagram of a layout structure of a transistor provided in an example of the present disclosure, and the transistor herein may be the first transistor 801, the second transistor 802, the third transistor 811, the fourth transistor 812, the fifth transistor 821, and the sixth transistor 822 in the above described example. As shown in FIG. 13, the transistor includes two first electrodes 901 and a second electrode 902 located between the two first electrodes 901, and the transistor further includes two gates 903. Here, the transistor may be a PMOS, the first electrode 901 may be a source, and the second electrode 902 may be a drain.

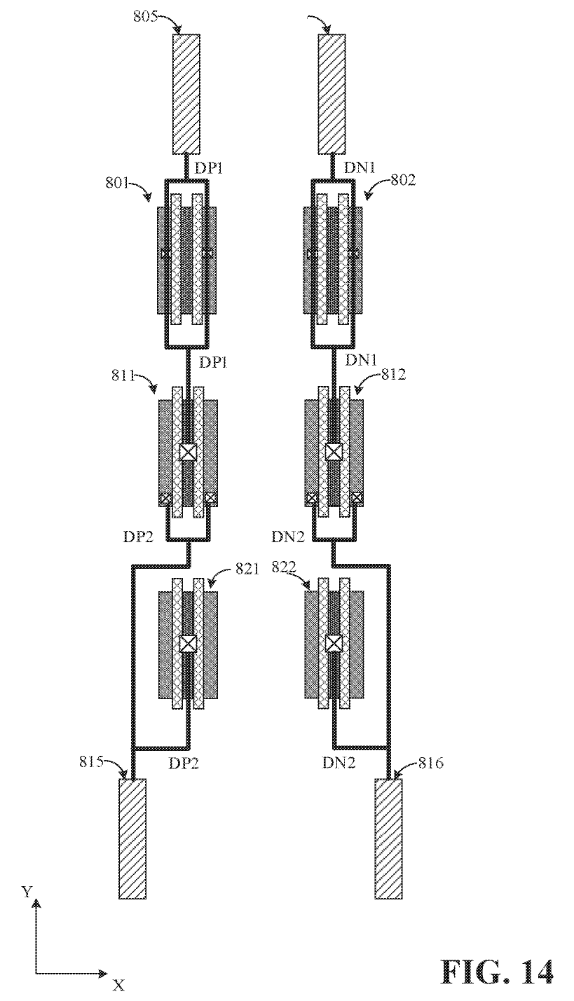

In some examples, FIG. 14 is a schematic diagram of a layout structure of a partial structure in an input buffer provided in an example of the present disclosure. Referring to FIG. 13 and FIG. 14, the gate of the third transistor 811 is coupled to the two first electrodes of the first transistor 801, the gate of the fourth transistor 812 is coupled to the two first electrodes of the second transistor 802, the gate of the fifth transistor 821 is coupled to the two first electrodes of the third transistor 811, and the gate of the sixth transistor 822 is coupled to the two first electrodes of the fourth transistor 812.

In some examples, with reference to FIG. 9, FIG. 10, FIG. 12, and FIG. 14, the first circuit 701 further includes a first resistor 805 and a second resistor 806, the second circuit 702 further includes a third resistor 815 and a fourth resistor 816, wherein the first resistor 805 and the second resistor 806 are located on a side of the first transistor pair 800 away from the second transistor pair 810 in the first direction, the first resistor 805 is coupled to the two first electrodes of the first transistor 801, and the second resistor 806 is coupled to the two first electrodes of the second transistor 802, the third resistor 815 and the fourth resistor 816 are located on a side of the third transistor pair 820 away from the second transistor pair 810 in the first direction, the third resistor 815 is coupled to the two first electrodes of the third transistor 811, and the fourth resistor 816 is coupled to the two first electrodes of the fourth transistor 812.

In some specific examples, referring to FIG. 14, the signal line DP1, the signal line DN1, the signal line DP2 and the signal line DN2 may each include a plurality of branches. Taking the signal line DP1 as an example, both ends of the signal line DP1 may be respectively coupled to the first resistor 805 and the gate of the third transistor 811, the middle portion of the signal line DP1 may include two branches, and each branch may be coupled to one first electrode of the first transistor 801 through a contact structure.

In the example of the present disclosure, on the basis of the fact that the first transistor pair 800, the second transistor pair 810 and the third transistor pair 820 are placed in a concentrated manner to reduce the length of the signal line, the transistors in the first transistor pair 800, the second transistor pair 810 and the third transistor pair 820 each include two first electrodes and a second electrode located between the two first electrodes, the gate of one transistor in the second transistor pair 810 is coupled to the two first electrodes of one transistor in the first transistor pair 800, and the gate of one transistor in the third transistor pair 820 is coupled to the two first electrodes of one transistor in the second transistor pair 810, so that current distribution may be more uniform, thereby improving reliability of voltage signal transmission.

In some examples, with reference to FIG. 11 and FIG. 12, the input buffer further includes: a fourth circuit 704 coupled to the third circuit 703, wherein the fourth circuit 704 includes a CMOS pass gate 840 and a first inverter 830 connected in parallel, and the sixth transistor 825 in the third transistor pair 820 is coupled to the first inverter 830; a fifth circuit 705 coupled to the fourth circuit 704, wherein the fifth circuit 705 includes a plurality of second inverters 850 connected in series, and the fourth circuit 704 is located between the third circuit 703 and the fifth circuit 705 in the second direction. Here, the second direction is perpendicular to the first direction, and the second direction is the X direction.

In some examples, with reference to FIG. 11 and FIG. 12, the CMOS pass gate 840 is located between the first inverter 830 and the third circuit 703 in the second direction, and the CMOS pass gate 840 includes: a seventh transistor 841 and an eighth transistor 842 arranged along the first direction, with the gate of the seventh transistor 841 and the gate of the eighth transistor 842 both extending in the first direction. Here, the seventh transistor 841 may be a PMOS in the CMOS pass gate 840, and the eighth transistor 842 may be an NMOS in the CMOS pass gate 840.

In the example of the present disclosure, the third transistor pair 820 is coupled to the transistor 831 in the first inverter 830 through the signal line DN3 extending in the second direction, the seventh transistor 841 and the eighth transistor 842 in the CMOS pass gate 840 are arranged along the first direction with the gates of the seventh transistor 841 and the eighth transistor 842 both extending in the first direction, thereby the size of the CMOS pass gate 840 in the second direction can be reduced, such that the length of the signal line DN3 can be reduced, the parasitic capacitance can be reduced, and the transmission speed of the voltage signal in the input buffer can be further improved.

In some examples, with reference to FIG. 9, FIG. 10, FIG. 12, and FIG. 14, the first circuit 701 further includes a transistor 803 and a transistor 804, the second circuit 702 further includes a transistor 813 and a transistor 814, wherein the transistor 803 and the transistor 804 are located on one of the two opposite sides of the first transistor pair 800 in the second direction, and the transistor 813 and the transistor 814 are located on one of the two opposite sides of the second transistor pair 810 in the second direction. The third circuit 703 further includes a transistor 823 located between the transistor 803, the transistor 804, the transistor 813 and the transistor 814, and the three transistor pairs in the second direction. The third circuit 703 further includes a transistor 824 and a transistor 825 located between the CMOS pass gate 840 and the third transistor pair 820 in the second direction. The fourth circuit 704 further includes a transistor 823, the fifth circuit 705 further includes a transistor 833, and the transistor 823 and the transistor 833 may be located on one of the two opposite sides of the first inverter 830 and the second inverter 850 in the first direction.

In the examples of the present disclosure, the first transistor pair, the second transistor pair and the third transistor pair that transmit the voltage signal stage by stage may be placed in a concentrated manner, so that the length of the signal line may be reduced, the parasitic capacitance of the signal line may be reduced, and the transmission speed of the voltage signal may be increased. The transistors in the first transistor pair, the second transistor pair and the third transistor pair each include two first electrodes and a second electrode located between the two first electrodes, with a gate of one transistor in the next transistor pair coupled to the two first electrodes of one transistor in the previous transistor pair, so that current distribution can be more uniform, thereby reliability of voltage signal transmission can be improved. The two transistors in the CMOS pass gate are arranged along the first direction with the gates of the two transistors extending in the first direction, thus the size of the CMOS pass gate in the second direction can be reduced, the length of the signal line used for connecting the third transistor pair and the first inverter can be reduced, the parasitic capacitance of the signal can be reduced, and the transmission speed of the voltage signal in the input buffer can be further improved.

Based on a similar concept as the input buffer described above, the present disclosure further provides a memory device, including an input/output interface, wherein the input/output interface includes an input buffer, and the input buffer includes: a first circuit and a second circuit coupled to the first circuit, wherein the first circuit includes a first transistor pair including a first transistor and a second transistor, and the first transistor and the second transistor each include two first electrodes and a second electrode located between the two first electrodes, the second circuit includes a second transistor pair including a third transistor and a fourth transistor, the first transistor pair and the second transistor pair are adjacent in a first direction, a gate of the third transistor is coupled to the two first electrodes of the first transistor, and a gate of the fourth transistor is coupled to the two first electrodes of the second transistor.

In some specific examples, the memory device may be the memory device 300 shown in FIG. 5 or the memory device 500 shown in FIG. 6, and the input/output interface may be the input/output interface 407 in the memory device 300 or the data input/output interface 505 in the memory device 500.

In some examples, the first transistor is configured to receive an input voltage and output a first voltage, the second transistor is configured to receive a reference voltage and output a second voltage, the third transistor is configured to receive the first voltage and output a third voltage, and the fourth transistor is configured to receive the second voltage and output a fourth voltage.

In some examples, the third transistor and the fourth transistor each include two first electrodes and a second electrode located between the two first electrodes, the input buffer further includes: a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

In some examples, the first transistor pair and the second transistor pair are adjacent in a first direction, and the third transistor pair and the second transistor pair are adjacent in the first direction.

In some examples, the first circuit further includes a first resistor and a second resistor, the second circuit further includes a third resistor and a fourth resistor, wherein the first resistor and the second resistor are located on a side of the first transistor pair away from the second transistor pair in the first direction, with the first resistor coupled to the two first electrodes of the first transistor, and the second resistor coupled to the two first electrodes of the second transistor, the third resistor and the fourth resistor are located on a side of the third transistor pair away from the second transistor pair in the first direction, with the third resistor coupled to the two first electrodes of the third transistor, and the fourth resistor coupled to the two first electrodes of the fourth transistor.

In some examples, the input buffer further includes: a fourth circuit coupled to the third circuit, wherein the fourth circuit includes a CMOS pass gate and a first inverter connected in parallel, and the sixth transistor is coupled to the first inverter; and a fifth circuit coupled to the fourth circuit, wherein the fifth circuit includes a plurality of second inverters connected in series, the fourth circuit is located between the third circuit and the fifth circuit in a second direction, and the second direction is perpendicular to the first direction.

In some examples, the CMOS pass gate is located between the first inverter and the third circuit in the second direction, the CMOS pass gate includes: a seventh transistor and an eighth transistor arranged along the first direction, with a gate of the seventh transistor and a gate of the eighth transistor both extending along the first direction.

Based on a similar concept as the above memory device, the present disclosure further provides a memory system, comprising the memory device according to any one of the above examples; and a memory controller coupled with at least one of the memory devices and configured to control the memory device.

In some examples, the memory controller may send a data signal to the memory device, and the input buffer in the input/output interface of the memory device may receive the data signal. Here, the input buffer may be the input buffer in any of the above examples, and both the speed and the reliability of the voltage signal transmitted by the input buffer are high, thereby the speed and reliability of transmission of the data signal between the memory controller and the memory device can be improved, so that the memory system meets higher performance requirements.

The features disclosed in the several device examples provided by the present disclosure may be arbitrarily combined without conflict to obtain a new device example.

The above descriptions are only specific examples of the present disclosure, but the protection scope of the present disclosure is not limited thereto, and any variations or replacements that can be easily thought of by those skilled in the art within the technical scope of the present disclosure, should be covered within the protection scope of the present disclosure.

What is claimed is:

1. An input buffer, comprising a first circuit and a second circuit coupled to the first circuit, wherein,
the first circuit includes a first transistor pair including a first transistor and a second transistor, the first transistor and the second transistor each including two first electrodes and a second electrode located between the two first electrodes; and
the second circuit includes a second transistor pair including a third transistor and a fourth transistor, with a gate of the third transistor coupled to the two first electrodes of the first transistor, and a gate of the fourth transistor coupled to the two first electrodes of the second transistor.

2. The input buffer of claim 1, wherein the first transistor is configured to receive an input voltage and output a first voltage;
the second transistor is configured to receive a reference voltage and output a second voltage;
the third transistor is configured to receive the first voltage and output a third voltage; and
the fourth transistor is configured to receive the second voltage and output a fourth voltage.

3. The input buffer of claim 1, wherein the third transistor and the fourth transistor each comprise two first electrodes and a second electrode located between the two first electrodes; and
the input buffer further comprises:
a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

4. The input buffer of claim 3, wherein the first transistor pair and the second transistor pair are adjacent in a first direction; and the third transistor pair and the second transistor pair are adjacent in the first direction.

5. The input buffer of claim 4, wherein the first circuit further comprises a first resistor and a second resistor; and the second circuit further comprises a third resistor and a fourth resistor, wherein,
the first resistor and the second resistor are located on a side of the first transistor pair away from the second transistor pair in the first direction, the first resistor is coupled to the two first electrodes of the first transistor, and the second resistor is coupled to the two first electrodes of the second transistor; and
the third resistor and the fourth resistor are located on a side of the third transistor pair away from the second transistor pair in the first direction, the third resistor is coupled to the two first electrodes of the third transistor, and the fourth resistor is coupled to the two first electrodes of the fourth transistor.

6. The input buffer of claim 4, further comprising:
a fourth circuit coupled to the third circuit, wherein the fourth circuit includes a complementary metal-oxide-semiconductor (CMOS) pass gate and a first inverter connected in parallel, and the sixth transistor is coupled to the first inverter; and
a fifth circuit coupled to the fourth circuit, wherein the fifth circuit includes a plurality of second inverters connected in series, the fourth circuit is located between the third circuit and the fifth circuit in a second direction, and the second direction is perpendicular to the first direction.

7. The input buffer of claim 6, wherein the CMOS pass gate is located between the first inverter and the third circuit in the second direction; and
the CMOS pass gate comprises:
a seventh transistor and an eighth transistor arranged along the first direction, with a gate of the seventh transistor and a gate of the eighth transistor both extending along the first direction.

8. A memory device comprising an input/output interface comprising an input buffer comprising a first circuit and a second circuit coupled to the first circuit, wherein,
the first circuit includes a first transistor pair including a first transistor and a second transistor, the first transistor and the second transistor each including two first electrodes and a second electrode located between the two first electrodes; and
the second circuit includes a second transistor pair including a third transistor and a fourth transistor, with a gate of the third transistor coupled to the two first electrodes of the first transistor, and a gate of the fourth transistor coupled to the two first electrodes of the second transistor.

9. The memory device of claim 8, wherein
the first transistor is configured to receive an input voltage and output a first voltage;
the second transistor is configured to receive a reference voltage and output a second voltage;
the third transistor is configured to receive the first voltage and output a third voltage; and
the fourth transistor is configured to receive the second voltage and output a fourth voltage.

10. The memory device of claim 8, wherein the third transistor and the fourth transistor each comprise two first electrodes and a second electrode located between the two first electrodes; and
the input buffer further comprises:
a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

11. The memory device of claim 10, wherein the first transistor pair and the second transistor pair are adjacent in a first direction; and the third transistor pair and the second transistor pair are adjacent in the first direction.

12. The memory device of claim 11, wherein the first circuit further comprises a first resistor and a second resistor; and the second circuit further comprises a third resistor and a fourth resistor, wherein,
the first resistor and the second resistor are located on a side of the first transistor pair away from the second transistor pair in the first direction, the first resistor is coupled to the two first electrodes of the first transistor, and the second resistor is coupled to the two first electrodes of the second transistor; and
the third resistor and the fourth resistor are located on a side of the third transistor pair away from the second transistor pair in the first direction, the third resistor is coupled to the two first electrodes of the third transistor, and the fourth resistor is coupled to the two first electrodes of the fourth transistor.

13. The memory device of claim 11, wherein the input buffer further comprises:
a fourth circuit coupled to the third circuit, wherein the fourth circuit includes a complementary metal-oxide-semiconductor (CMOS) pass gate and a first inverter connected in parallel, and the sixth transistor is coupled to the first inverter; and
a fifth circuit coupled to the fourth circuit, wherein the fifth circuit includes a plurality of second inverters connected in series, the fourth circuit is located between the third circuit and the fifth circuit in a second direction, and the second direction is perpendicular to the first direction.

14. The memory device of claim 13, wherein the CMOS pass gate is located between the first inverter and the third circuit in the second direction; and
the CMOS pass gate comprises:
a seventh transistor and an eighth transistor arranged along the first direction, with a gate of the seventh transistor and a gate of the eighth transistor both extending along the first direction.

15. A memory system, comprising:
a memory device, comprising an input/output interface comprising an input buffer comprising a first circuit and a second circuit coupled to the first circuit, wherein,
the first circuit includes a first transistor pair including a first transistor and a second transistor, the first transistor and the second transistor each including two first electrodes and a second electrode located between the two first electrodes; and
the second circuit includes a second transistor pair including a third transistor and a fourth transistor, with a gate of the third transistor coupled to the two first electrodes of the first transistor, and a gate of the fourth transistor coupled to the two first electrodes of the second transistor; and
a memory controller coupled with at least one memory device and configured to control the memory device.

16. The memory system of claim 15, wherein
the first transistor is configured to receive an input voltage and output a first voltage;
the second transistor is configured to receive a reference voltage and output a second voltage;
the third transistor is configured to receive the first voltage and output a third voltage; and
the fourth transistor is configured to receive the second voltage and output a fourth voltage.

17. The memory system of claim 15, wherein the third transistor and the fourth transistor each comprise two first electrodes and a second electrode located between the two first electrodes; and
the input buffer further comprises:
a third circuit coupled to the second circuit, wherein the third circuit includes a third transistor pair including a fifth transistor and a sixth transistor, with a gate of the fifth transistor coupled to the two first electrodes of the third transistor, and a gate of the sixth transistor coupled to the two first electrodes of the fourth transistor.

18. The memory system of claim 17, wherein the first transistor pair and the second transistor pair are adjacent in a first direction; and the third transistor pair and the second transistor pair are adjacent in the first direction.

19. The memory system of claim 18, wherein the first circuit further comprises a first resistor and a second resistor; and the second circuit further comprises a third resistor and a fourth resistor, wherein,
the first resistor and the second resistor are located on a side of the first transistor pair away from the second transistor pair in the first direction, the first resistor is coupled to the two first electrodes of the first transistor, and the second resistor is coupled to the two first electrodes of the second transistor; and
the third resistor and the fourth resistor are located on a side of the third transistor pair away from the second transistor pair in the first direction, the third resistor is coupled to the two first electrodes of the third transistor, and the fourth resistor is coupled to the two first electrodes of the fourth transistor.

20. The memory system of claim 18, wherein the input buffer further comprises:
a fourth circuit coupled to the third circuit, wherein the fourth circuit includes a complementary metal-oxide-semiconductor (CMOS) pass gate and a first inverter connected in parallel, and the sixth transistor is coupled to the first inverter; and
a fifth circuit coupled to the fourth circuit, wherein the fifth circuit includes a plurality of second inverters connected in series, the fourth circuit is located between the third circuit and the fifth circuit in a second direction, and the second direction is perpendicular to the first direction.
